(19) United States
(12) Patent Application Publication
(10) Pub. No.: US 2013/0032897 A1
(43) Pub. Date: Feb. 7, 2013

(54) MOSFET GATE ELECTRODE EMPLOYING ARSENIC-DOPED SILICON-GERMANIUM ALLOY LAYER

(71) Applicants: Vijay Narayanan, New York, NY (US); Christopher V. Baiocco, Newburgh, NY (US); Weipeng Li, Beacon, NY (US); Helen Wang, LaGrangeville, NY (US)

(72) Inventors: Vijay Narayanan, New York, NY (US); Christopher V. Baiocco, Newburgh, NY (US); Weipeng Li, Beacon, NY (US); Helen Wang, LaGrangeville, NY (US)

(73) Assignee: International Business Machines Corporation, Armonk, NY (US)

(21) Appl. No.: 13/196,106

(22) Filed: Aug. 2, 2011

(51) Int. Cl. H01L 21/28; H01L 29/78

(52) U.S. Cl. 257/410; 438/591; 257/E21.19; 257/E29.255

(57) ABSTRACT

A stack of a gate dielectric layer, a metallic material layer, an amorphous silicon-germanium alloy layer, and an amorphous silicon layer is deposited on a semiconductor substrate. In one embodiment, the amorphous silicon-germanium alloy layer is deposited as an in-situ amorphous arsenic-doped silicon-germanium alloy layer. In another embodiment, the amorphous silicon-germanium alloy layer is deposited as intrinsic semiconductor material layer, and arsenic is subsequently implanted into the amorphous silicon-germanium alloy layer. The stack is patterned and annealed to form a gate electrode.

### BACKGROUND

The present disclosure generally relates to a semiconductor structure, and particularly to a field effect transistor employing an arsenic-doped silicon-germanium alloy layer contacting a metallic gate electrode portion, and methods of manufacturing the same.

A metal gate structure in a field effect transistor generally includes a gate dielectric and a gate electrode contacting the gate electrode. The gate electrode can include a metallic material portion and a doped semiconductor material portion. In general, a Schottky barrier is present between the metallic material portion and the doped semiconductor material portion.

The Schottky barrier provides an interfacial resistance between the metallic material portion and the doped semiconductor material portion. The interfacial resistance adversely affects device characteristics of the field effect transistor at high operational frequencies, and especially in the frequency range above 1 GHz.

### BRIEF SUMMARY

A stack of a gate dielectric layer, a metallic material layer, an amorphous silicon-germanium alloy layer, and an amorphous silicon layer is deposited on a semiconductor substrate. In one embodiment, the amorphous silicon-germanium alloy layer is deposited as an in-situ amorphous arsenic-doped silicon-germanium alloy layer. In another embodiment, the amorphous silicon-germanium alloy layer is deposited as an intrinsic semiconductor material layer, and arsenic is subsequently implanted into the amorphous silicon-germanium alloy layer. The stack is patterned and annealed to form a gate electrode. Compared to a polysilicon layer derived from an amorphous silicon layer, the presence of germanium in the amorphous silicon-germanium alloy layer results in enhanced arsenic diffusion, reduced resistivity, and reduced band gap in a resulting arsenic-doped polycrystalline silicon-germanium alloy layer after an anneal, thereby providing a reduction in the Schottky barrier in a gate electrode.

According to an aspect of the present disclosure, a method of forming a semiconductor structure is provided, which includes: forming a gate dielectric layer on a semiconductor substrate; forming a metallic material layer on the gate dielectric layer; forming a layer stack of an amorphous silicon-germanium alloy layer and an amorphous arsenic-doped silicon layer on the metallic material layer; forming a gate stack by patterning the layer stack, the metallic material layer, and the gate dielectric layer; and annealing the gate stack, wherein a gate electrode including a stack of a polycrystalline arsenic-doped silicon-germanium alloy portion and an polycrystalline arsenic-doped silicon portion is formed within the gate stack.

According to another aspect of the present disclosure, a semiconductor structure including a field effect transistor is provided. The field effect transistor (FET) includes a gate stack. The gate stack includes: a gate dielectric located on a semiconductor substrate; a metallic material portion contacting the gate dielectric; a polycrystalline arsenic-doped silicon-germanium alloy portion contacting the metallic material portion; and a polycrystalline arsenic-doped silicon portion contacting the polycrystalline arsenic-doped silicon-germanium alloy portion.

### BRIEF DESCRIPTION OF SEVERAL VIEWS OF THE DRAWINGS

In the present disclosure, drawings that are labeled with the same numeric label represent the same stage of a manufacturing process. Drawings that are labeled with the suffix “A” are top-down views. Drawings that are labeled with the suffix “B” are vertical cross-sectional views along a vertical plane B-B′ in the top-down view labeled with the same numeric label and the suffix “A.”

FIGS. 1A and 1B are views of an exemplary structure after formation of a layer stack including a gate dielectric layer and a metallic material layer according to an embodiment of the present disclosure.

FIGS. 2A and 2B are views of the exemplary structure after formation of another layer stack including an amorphous silicon-germanium alloy layer and an amorphous arsenic-doped silicon layer on the metallic material layer according to an embodiment of the present disclosure.

FIGS. 3A and 3B are views of the exemplary structure after patterning of the amorphous arsenic-doped silicon layer, the amorphous silicon-germanium alloy layer, the metallic material layer, and the gate dielectric layer to form a gate stack according to an embodiment of the present disclosure.

FIGS. 4A and 4B are views of the exemplary structure after formation of source and drain extension regions and a gate spacer according to an embodiment of the present disclosure.

FIGS. 5A and 5B are views of the exemplary structure after formation of raised source and drain regions and buried source and drain regions and conversion of an amorphous arsenic-doped silicon portion and an amorphous silicon-germanium alloy portion into a polycrystalline arsenic-doped portion and a polycrystalline arsenic-doped silicon-germanium alloy portion, respectively, according to an embodiment of the present disclosure.

FIGS. 6A and 6B are views of the exemplary structure after formation of a contact-level dielectric layer and contact via structures therein according to an embodiment of the present disclosure.

### DETAILED DESCRIPTION

As stated above, the present disclosure relates to a semiconductor structure, and particularly to a field effect transistor employing arsenic-doped silicon-germanium alloy layer contacting a metallic gate electrode portion, and methods of manufacturing the same, which are now described in detail with accompanying figures. Like and corresponding elements mentioned herein and illustrated in the drawings are referred to by like reference numerals. The drawings are not necessarily drawn to scale.

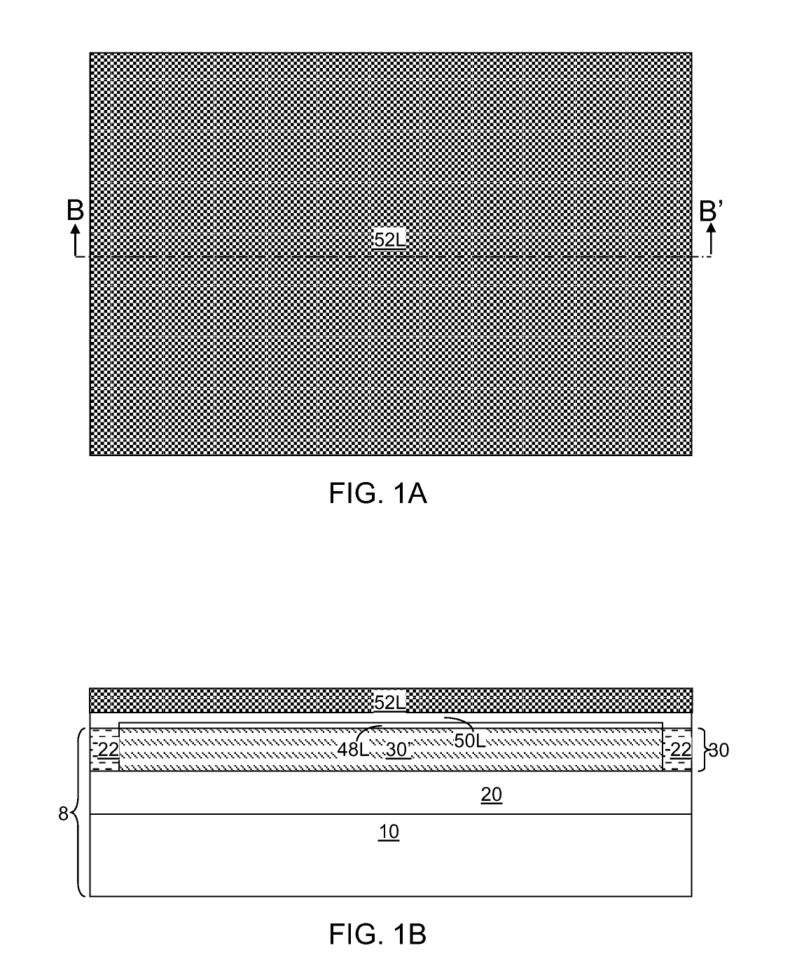

Referring to FIGS. 1A and 1B, an exemplary structure according to an embodiment of the present disclosure includes a semiconductor substrate 8 and a layer stack formed thereupon. The semiconductor substrate 8 can be a bulk semiconductor substrate including an amorphous, polycrystalline, or a single crystalline semiconductor material, or can be a semiconductor-on-insulator substrate including a stack, from bottom to top, of a handle substrate 10, a buried insulator layer 20, and a top semiconductor layer 30. The handle substrate 10 can include a semiconductor material, a dielectric material, or a conductive material provided that the material of the handle substrate 10 provides sufficient structural support to the buried insulator layer 20 and the top semiconductor layer 30 thereupon so that the semiconductor substrate 8 can be physically handled. The buried insulator layer 20 includes a dielectric material such as silicon oxide, silicon nitride, silicon oxynitride, or a combination thereof.

The top semiconductor layer 30 includes a semiconductor material, which may be selected from, but is not limited to, silicon, germanium, silicon-germanium alloy, silicon carbon alloy, silicon-germanium alloy-carbon alloy, gallium arsenide, indium arsenide, indium phosphide, III-V compound semiconductor materials, II-VI compound semiconductor materials, organic semiconductor materials, and other compound semiconductor materials. The same semiconductor materials can be employed as the semiconductor material of a bulk semiconductor substrate if the semiconductor substrate 8 is a bulk semiconductor substrate. In one embodiment, the semiconductor material of the top semiconductor layer 30 (or the bulk semiconductor substrate) can be a single crystalline silicon-containing semiconductor material. The single crystalline silicon-containing semiconductor material can be, for example, single crystalline silicon, a single crystalline silicon carbon alloy, a single crystalline silicon-germanium alloy, or a single crystalline silicon-germanium alloy carbon alloy.

Various portions of the top semiconductor layer 30 (or various top portion of the bulk semiconductor substrate) can be appropriately doped either with p-type electrical dopant atoms or with n-type electrical dopant atoms. The electrical dopant concentration may be from 1.0×10¹⁵/cm³ to 1.0×10¹⁹/cm³, and typically from 1.0×10¹⁶/cm³ to 3.0×10¹⁸/cm³, although lesser and greater electrical dopant concentrations are contemplated herein also. The semiconductor substrate 8 may, or may not, have a built-in stress in the top semiconductor layer 30 or in the top portions of the bulk semiconductor substrate.

Shallow trench isolation structures 22 can be formed in the top semiconductor layer 30 (or a top portion of the bulk semiconductor substrate), for example, by forming shallow trenches therein, filling the shallow trenches with a dielectric material, and removing excess dielectric material from above the top surface of the semiconductor substrate 8. The remaining semiconductor material portions of the top semiconductor layer 30 are herein referred to as top semiconductor portions 30′. While the present disclosure is hereafter described for a case in which the semiconductor substrate 8 is an SOI substrate, embodiments in which the semiconductor substrate 8 is a bulk semiconductor substrate can also be employed. The conductivity type of doping in the top semiconductor portion 30′ illustrated in FIGS. 1A and 1B is herein referred to a first conductivity type, which can be p-type or n-type.

A chemical interfacial layer 48L may be formed on the exposed semiconductor surface of the top semiconductor layer 30. The chemical interfacial layer 48L is optional, i.e., may, or may not, be present. A high dielectric constant (high-k) gate dielectric layer 50L is formed directly on the top surface of the chemical interfacial layer 48L. Even in the case the chemical interfacial layer 48L is not deposited in a dedicated processing step, the deposition of the high-k gate dielectric layer 30L and subsequent thermal processes can lead to formation of the chemical interfacial layer 48L. The chemical interfacial layer 48L, which is an interfacial layer between the top semiconductor layer 30 and the high-k gate dielectric layer 50L, includes a semiconductor oxide, i.e., the oxide of the semiconductor material of the top surface of the top semiconductor layer 20.

The chemical interfacial layer 48L may be formed by treatment of exposed semiconductor surfaces with a chemical. For example, the process step for this wet chemical oxidation may include treating a cleaned semiconductor surface (such as a semiconductor surface treated with hydrofluoric acid) with a mixture of ammonium hydroxide, hydrogen peroxide and water (in a 1:1:5 ratio) at 65° C. Alternately, the chemical interfacial layer can also be formed by treating the HF-last semiconductor surface in ozonated aqueous solutions, with the ozone concentration usually varying from, but not limited to: 2 parts per million (ppm) to 40 ppm. The chemical interfacial layer 48L helps minimize mobility degradation in the top semiconductor portions 30′ due to high-k dielectric material in the high-k gate dielectric layer 50L. The scalability of the effective oxide thickness (EOT) is limited by the thickness of the chemical interfacial layer 48L. In case the top semiconductor portions 20′ includes single crystalline silicon, the chemical interfacial layer 48L is a silicon oxide layer. Typically, the thickness of the chemical interfacial layer 48L is from 0.4 nm to 1 nm, although lesser and greater thicknesses are also contemplated herein.

Alternately or additionally, the chemical interfacial layer 48L may include a silicon oxynitride (SiON) layer. The silicon oxynitride layer maybe formed by either by a combination of plasma oxidation/nitridation processes or by thermal oxidation and nitridation processes.

A high-k gate dielectric layer 50L is formed above a top surface of the semiconductor substrate 8. The high-k gate dielectric layer 50L includes a material having a “high dielectric constant material.” A “high dielectric constant material,” or a “high-k dielectric material,” herein refers to a dielectric material having a dielectric constant greater than 8.0. The high-k gate dielectric layer 50L can include a dielectric metal oxide, which is a high-k material containing a metal and oxygen, and is known in the art as high-k gate dielectric materials.

Dielectric metal oxides can be deposited by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. The high-k gate dielectric layer 50L is deposited as a blanket layer directly on the entirety of the top surface of the chemical interfacial layer 48 or the top surfaces of the semiconductor substrate 8, if a chemical interfacial layer is not separately formed. Exemplary high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlₓN_{y}, Y₂OₓN_{y}, a silicate thereof, and an alloy thereof. Each value of x is independently from 0.5 to 3 and each value of y is independently from 0 to 2. The thickness of the high-k gate dielectric layer 50L can be from 0.3 nm to 3 nm, and preferably from 0.6 nm to 2 nm, although lesser and greater thicknesses can also be employed.

A metallic material layer 52L is deposited directly on the top surface of the high-k gate dielectric layer 50L. The metallic material layer 52L may be formed, for example, by chemical vapor deposition (CVD), physical vapor deposition (PVD), or atomic layer deposition (ALD). The material of the metallic material layer 52L includes a metallic material, and can be an elemental metal, an alloy of at least two elemental metals, a conductive transition metal nitride, a conductive transition metal carbide, any other conductive alloy of at least one metal and a non-metallic element, or a combination thereof. The metallic material layer 52L can be a single homogenous metallic material layer, or can be a stack of a plurality of metallic material layers having different compositions.

In one embodiment, the metallic material layer 52L can include a metallic compound of at least one transition metal and a non-metallic element. If the non-metallic element is nitrogen, the metallic compound is a transition metal nitride. If the non-metallic element is carbon, the metallic compound is a transition metal carbide. For example, the metallic compound may be selected from TiN, TiC, TaN, TaC, a TiN/TaAlN stack, and a TiN/Al/TiN stack, and a combination thereof. As used herein, transition metals include elements from Group 3B, 4B, 5B, 6B, 7B, 8B, 1B, and 2B and Lanthanides and Actinides in the Periodic Table of the Elements. The thickness of the metallic material layer 52L may be from 1 nm to 10 nm, and preferably from 3 nm to 10 nm, although lesser and greater thicknesses are also contemplated herein.

In one embodiment, the metallic material layer 52L includes a metallic barrier material that blocks diffusion of metallic elements through the metallic material layer. Materials that block diffusion of metallic elements include TiN, TiC, TaN, TaC, a TiN/TaAlN stack, and a TiN/Al/TiN stack.

The metallic material layer 52L can include a work function material layer, i.e., a material layer employed to control the work function of a gate electrode of a transistor to be subsequently formed. The work function material layer includes a material having a work function between the valence band of the semiconductor material of a top semiconductor portion 30′ (or of a top portion of a bulk semiconductor substrate) and the conduction band of the semiconductor material of the top semiconductor portion 30′ (or of the top portion of a bulk semiconductor substrate). The work function of the work function material layer can be closer to the valence band of the semiconductor material of the top semiconductor portion 30′ or to the conduction band of the semiconductor material of the top semiconductor portion 30′. The energy level at the middle of the band gap of the semiconductor material of the top semiconductor portion 30′ is referred to as a mid-bandgap energy level.

In one embodiment, the metallic material layer can include a metallic material having a work function that is between the mid-bandgap energy level of the semiconductor material of the top semiconductor portion 30′ (or of the top portion of a bulk semiconductor substrate) and the balance band energy level of the semiconductor material. If the semiconductor material of the top semiconductor portion 30′ is doped or undoped silicon, the metallic material layer can include a “silicon valence band edge metal,” i.e., a metal having a work function between the mid-bandgap energy level of silicon and the balance band energy level of silicon. Silicon valence band edge metals include, but are not limited to, Pt, Rh, Ir, Ru, Cu, Os, Be, Co, Pd, Te, Cr, Ni, TiN, and alloys thereof.

In another embodiment, the metallic material layer includes a metallic material having a work function that is between the mid-bandgap energy level of the semiconductor material and the conduction band energy level of the semiconductor material. If the semiconductor material of the top semiconductor portion 30′ is doped or undoped silicon, the metallic material layer can include a “silicon conduction band edge metal,” i.e., a metal having a work function between the mid-bandgap energy level of silicon and the conduction band energy level of silicon. Silicon conduction band edge metals include, but are not limited to, Hf, Ti, Zr, Cd, La, Tl, Yb, Al, Ce, Eu, Li, Pb, Tb, Bi, In, Lu, Nb, Sm, V, Zr, Ga, Mg, Gd, Y, and TiAl, and alloys thereof.

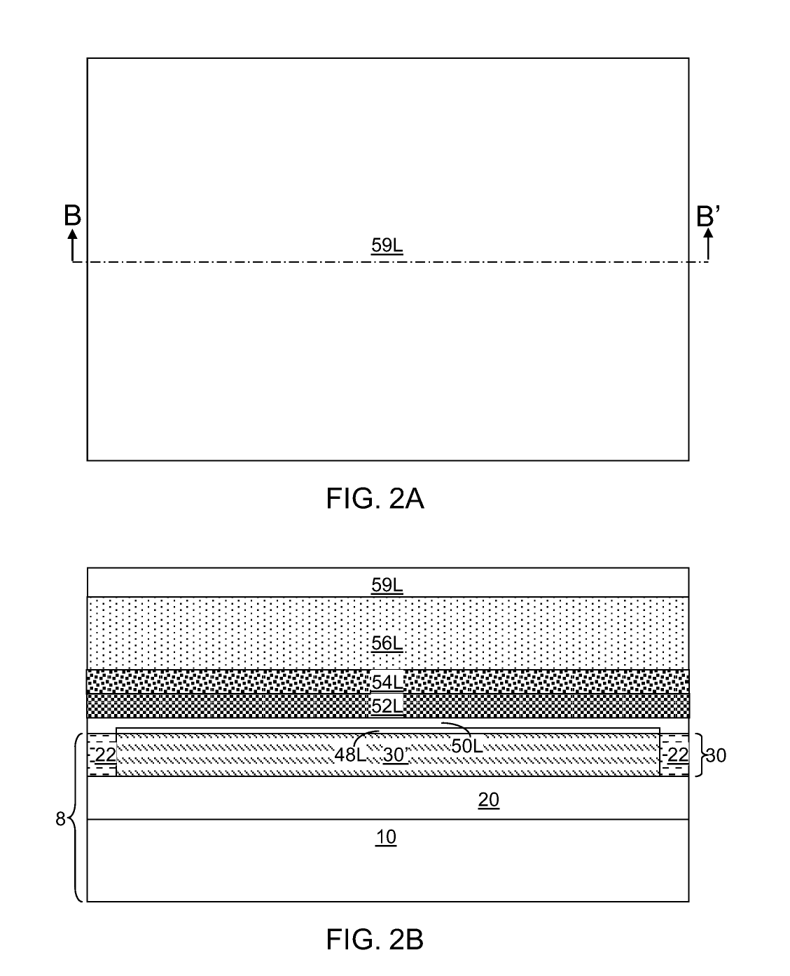

Referring to FIGS. 2A and 2B, another layer stack including an amorphous silicon-germanium alloy layer 54L, an amorphous arsenic-doped silicon layer 56L, and optionally a gate cap dielectric layer 59L is deposited on the metallic material layer 52L.

The amorphous silicon-germanium alloy layer 54L can be deposited, for example, by chemical vapor deposition (CVD), vacuum evaporation, or molecular beam deposition (MBE). The temperature of the deposition process is selected to prevent formation of a polycrystalline material and to maintain the deposited material as an amorphous material. For example, and in one embodiment, the temperature of the deposition process can be from 0° C. to 580° C. In another embodiment, the temperature of the deposition process can be from 0° C. to 520° C. in order to maintain the deposited alloy of silicon and germanium as an amorphous material.

The thickness of the amorphous silicon-germanium alloy layer 54L can be from 2 nm to 50 nm, although lesser and greater thicknesses can also be employed. The ratio of silicon to germanium in the amorphous silicon-germanium alloy layer 54L can be from 1:19 to 19:1. In one embodiment, the ratio of silicon to germanium in the amorphous silicon-germanium alloy layer 54L can be from 1:9 to 9:1. In another embodiment, the ratio of silicon to germanium in the amorphous silicon-germanium alloy layer 54L can be from 1:3 to 3:1. In yet another embodiment, the atomic concentration of germanium in the amorphous silicon-germanium alloy layer 54L can be from 1% to 80%. In still another embodiment, the atomic concentration of germanium in the amorphous silicon-germanium alloy layer 54L can be from 1% to 50%.

If a CVD process is employed to deposit the amorphous silicon-germanium alloy layer 54L, the CVD process can be, for example, a low pressure chemical vapor deposition (LPCVD) process or a plasma enhanced chemical vapor deposition (PECVD) process. During the CVD process, at least one first reactant gas for deposition of silicon and at least one second reactant gas for deposition of germanium can be simultaneously or alternately flowed into a process chamber in which the exemplary structure is placed so that top surface of the metallic material layer 52L is exposed. The at least one first reactant gas includes, for example, SiH₄, SiH₂Cl₂, SiHCl₃, SiCl₄, Si₂H₆, or a combination thereof. The at least one second reactant gas includes, for example, GeH₄, GeH₂Cl₂, Ge₂H₆, or a combination thereof.

In one embodiment, the amorphous silicon-germanium alloy layer 54L is deposited as an intrinsic amorphous silicon-germanium alloy layer, i.e., a layer of an amorphous silicon-germanium alloy. In this embodiment, the amorphous silicon-germanium alloy layer 54L does not include an electrical dopant. As used herein, an electrical dopant is an element that provides a p-type doping or an n-type doping to a semiconductor material. Exemplary electrical dopants include B, Al, Ga, and In, which provide a p-type doping to a semiconductor material, and P, As, and Sb, which provide an n-type doping to a semiconductor material.

In another embodiment, the amorphous silicon-germanium alloy layer 54L is deposited as an amorphous arsenic-doped silicon-germanium alloy layer, i.e., a layer of an amorphous arsenic-doped silicon-germanium alloy. In this embodiment, in-situ arsenic doping can be employed during a CVD process, a vacuum evaporation process, or an MBE process. For example, an electrical dopant gas such as AsH₃ can be flowed into the process chamber concurrently or alternately with the flow of the at least one first reactant gas and the at least one second reactant gas. Alternately, arsenic can be provided in atomic form or as an electrical dopant gas (such as AsH₃) during a vacuum evaporation process or an MBE process. The concentration of arsenic in the amorphous silicon-germanium alloy layer 54L can be from 3.0×10¹⁹/cm³ to 3.0×10²¹/cm³, although lesser and greater arsenic concentrations can also be employed.

The amorphous silicon layer 56L can be deposited, for example, by chemical vapor deposition (CVD), vacuum evaporation, or molecular beam deposition (MBE). The temperature of the deposition process is selected to prevent formation of a polycrystalline material and to maintain the deposited material as an amorphous material. For example, and in one embodiment, the temperature of the deposition process can be from 0° C. to 580° C. In another embodiment, the temperature of the deposition process can be from 0° C. to 550° C. in order to maintain the deposited silicon as an amorphous material. The thickness of the amorphous silicon layer 56L can be from 20 nm to 500 nm, although lesser and greater thicknesses can also be employed.

If a CVD process is employed to deposit the amorphous silicon layer 56L, the CVD process can be, for example, a low pressure chemical vapor deposition (LPCVD) process or a plasma enhanced chemical vapor deposition (PECVD) process. During the CVD process, at least one reactant gas for deposition of silicon is flowed into a process chamber in which the exemplary structure is placed so that top surface of the amorphous silicon-germanium alloy layer 54L is exposed. The at least one reactant gas includes, for example, SiH₄, SiH₂Cl₂, SiHCl₃, SiCl₄, Si₂H₆, or a combination thereof.

In one embodiment, the amorphous silicon layer 56L is deposited as an intrinsic amorphous silicon layer, i.e., a layer of an amorphous silicon. In this embodiment, the amorphous silicon layer 56L does not include an electrical dopant.

In another embodiment, the amorphous silicon layer 56L is deposited as an amorphous arsenic-doped silicon layer, i.e., a layer of an amorphous arsenic-doped silicon. In this embodiment, in-situ arsenic doping can be employed during a CVD process, a vacuum evaporation process, or an MBE process. For example, an electrical dopant gas such as AsH₃ can be flowed into the process chamber concurrently or alternately with the flow of the at least one reactant gas. Alternately, arsenic can be provided in atomic form or as an electrical dopant gas (such as AsH₃) during a vacuum evaporation process or an MBE process. The concentration of arsenic in the amorphous silicon layer 56L can be from 3.0×10¹⁹/cm³ to 3.0×10²¹/cm³, although lesser and greater arsenic concentrations can also be employed.

The gate cap dielectric layer 59L can be optionally deposited on the amorphous silicon layer 56L, for example, by chemical vapor deposition. The gate cap dielectric layer includes a dielectric material such as silicon oxide, silicon nitride, silicon oxynitride, or a combination thereof. The thickness of the gate cap dielectric layer 59L can be from 3 nm to 60 nm, although lesser and greater thicknesses can also be employed.

The stack of the amorphous silicon-germanium alloy layer 54L and the amorphous silicon layer 56L can be one of the following four combinations. A first combination is a stack of an amorphous intrinsic silicon-germanium alloy layer and an amorphous intrinsic silicon layer. A second combination is a stack of an amorphous arsenic-doped silicon-germanium alloy layer and an amorphous intrinsic silicon layer. A third combination is a stack of an amorphous intrinsic silicon-germanium alloy layer and an amorphous arsenic-doped silicon layer. A fourth combination is a stack of an amorphous arsenic-doped silicon-germanium alloy layer and an amorphous arsenic-doped silicon layer.

In the case of the first combination and the second combination, arsenic is implanted into the amorphous silicon layer 56L, which is an amorphous intrinsic silicon layer prior to the implantation, so that the amorphous silicon layer 56L becomes an amorphous arsenic-doped silicon layer. The concentration of arsenic in the amorphous silicon layer 56L can be from 1.0×10²⁰/cm³ to 5.0×10²¹/cm³, although lesser and greater arsenic concentrations can also be employed. If a gate cap dielectric layer 59L is formed, the implantation of arsenic into the amorphous silicon layer 56L can be performed prior to, or after, formation of the gate cap dielectric layer 59L.

The arsenic atoms may, or may not, be implanted into the amorphous silicon-germanium alloy layer 54L during the ion implantation. If the arsenic atoms are implanted into the amorphous silicon-germanium alloy layer 54L during the ion implantation, an amorphous intrinsic silicon-germanium alloy layer is converted into an amorphous arsenic-doped silicon-germanium alloy layer in the case of the first combination, or the concentration of arsenic in an amorphous arsenic-doped silicon-germanium alloy layer increases in the case of the second combination. If the arsenic atoms are not implanted into the amorphous silicon-germanium alloy layer 54L during the ion implantation (for example, by selecting the energy of the implanted arsenic ions insufficient to reach the amorphous silicon-germanium alloy layer 54L), an amorphous intrinsic silicon-germanium alloy layer remains as an amorphous intrinsic silicon-germanium alloy layer in the case of the first combination, or the concentration of arsenic in an amorphous arsenic-doped silicon-germanium alloy layer remains unchanged in the case of the second combination.

In the case of the third combination and the fourth combination, implantation of arsenic may, or may not, be performed. In an embodiment in which arsenic is implanted into the amorphous silicon layer 56L for the third or fourth combination, the arsenic concentration of the amorphous silicon layer 56L increases after ion implantation. The concentration of arsenic in the amorphous silicon layer 56L after the implantation of arsenic can be from 1.0×10²⁰/cm³ to 5.0×10²¹/cm³, although lesser and greater arsenic concentrations can also be employed. If a gate cap dielectric layer 59L is formed, the implantation of arsenic into the amorphous silicon layer 56L can be performed prior to, or after, formation of the gate cap dielectric layer 59L.

In an embodiment in which arsenic is implanted into the amorphous silicon layer 56L for the third or fourth combination, the arsenic atoms may, or may not, be implanted into the amorphous silicon-germanium alloy layer 54L during the ion implantation. If the arsenic atoms are implanted into the amorphous silicon-germanium alloy layer 54L during the ion implantation, an amorphous intrinsic silicon-germanium alloy layer is converted into an amorphous arsenic-doped silicon-germanium alloy layer in the case of the third combination, or the concentration of arsenic in an amorphous arsenic-doped silicon-germanium alloy layer increases in the case of the fourth combination. If the arsenic atoms are not implanted into the amorphous silicon-germanium alloy layer 54L during the ion implantation (for example, by selecting the energy of the implanted arsenic ions insufficient to reach the amorphous silicon-germanium alloy layer 54L), an amorphous intrinsic silicon-germanium alloy layer remains as an amorphous intrinsic silicon-germanium alloy layer in the case of the third combination, or the concentration of arsenic in an amorphous arsenic-doped silicon-germanium alloy layer remains unchanged in the case of the fourth combination.

In an embodiment in which arsenic is not implanted into the amorphous silicon layer 56L for the third or fourth combination, the composition of the amorphous silicon layer 56L remains unchanged. Likewise, the composition of the amorphous silicon-germanium alloy layer 54L remains unchanged.

Thus, for the second and fourth combinations, the stack of the amorphous silicon-germanium alloy layer 54L and the amorphous silicon layer 56L is a stack of an amorphous arsenic-doped silicon-germanium alloy layer and an amorphous arsenic-doped silicon layer at the end of the processing steps of FIGS. 2A and 2B.

For the first and third combinations, depending on whether an arsenic implantation step is performed or not and depending on the depth of ion implantation during the arsenic implantation step, the amorphous silicon-germanium alloy layer 54L may, or may not be doped with arsenic at the end of the processing steps of FIGS. 2A and 2B. Specifically, the stack of the amorphous silicon-germanium alloy layer 54L and the amorphous silicon layer 56L can be a stack of an amorphous arsenic-doped silicon-germanium alloy layer and an amorphous arsenic-doped silicon layer at the end of the processing steps of FIGS. 2A and 2B, or alternately, can be a stack of an amorphous intrinsic silicon-germanium alloy layer and an amorphous arsenic-doped silicon layer at the end of the processing steps of FIGS. 2A and 2B.

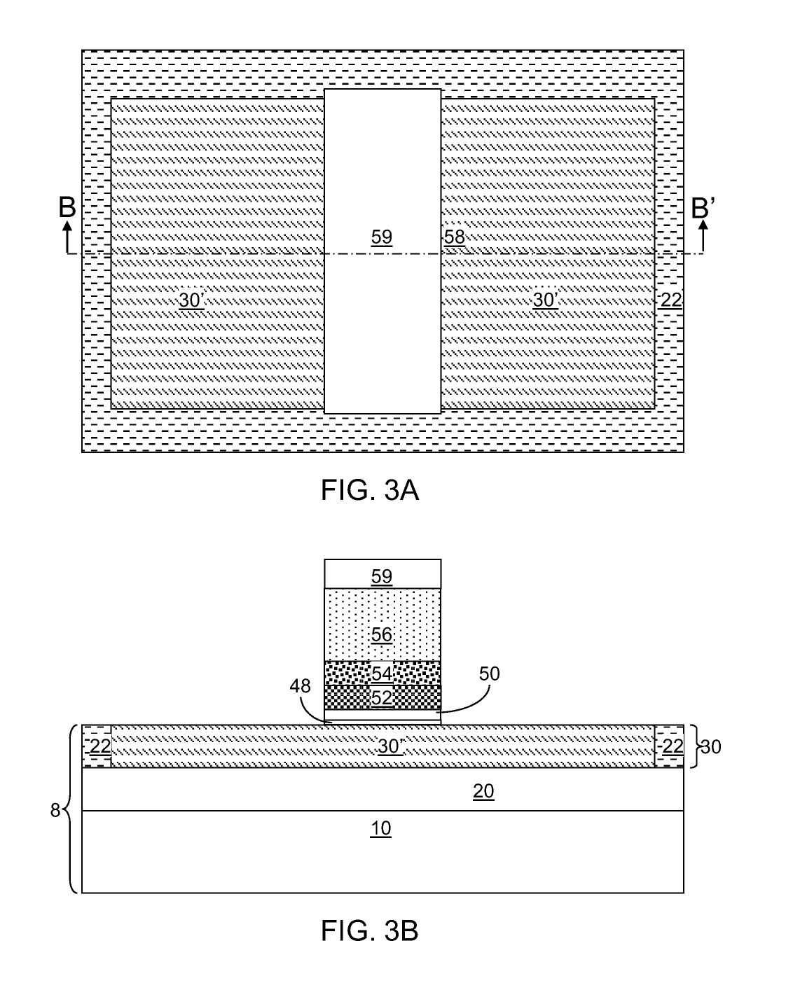

Referring to FIGS. 3A and 3B, the layer stack of the optional gate cap dielectric layer 59L, the amorphous silicon layer 56L which is an amorphous arsenic-doped silicon layer, the amorphous silicon-germanium alloy layer 54L, the metallic material layer 52L, the gate dielectric layer 502L, and the optional chemical interfacial layer 48L to form a gate stack. For example, a photoresist (not shown) can be applied to the top surface of the gate cap dielectric layer 59L (if present) or the top surface of the amorphous silicon layer 56L (if a gate cap dielectric layer is not present). The photoresist is patterned by lithographic exposure and development. The pattern in the photoresist is transferred into the underlying layer stack, for example, by an anisotropic etch.

A remaining portion of the gate cap dielectric layer 59L is herein referred to as a gate cap dielectric 59, a remaining portion of the amorphous silicon layer 56L is herein referred to as an amorphous silicon portion 56, a remaining portion of the amorphous silicon-germanium alloy layer 54L is herein referred to as an amorphous silicon-germanium alloy portion 54, a remaining portion of the metallic material layer 52L is herein referred to as a metallic material portion 52, a remaining portion of the high-k gate dielectric layer 50L is herein referred to as a high-k gate dielectric 50, and a remaining portion of the chemical interfacial layer 48L is herein referred to as a chemical oxide portion 48. The vertical stack of the optional chemical oxide portion 48, the high-k gate dielectric 50, the metallic material portion 52, the amorphous silicon-germanium alloy portion 54, the amorphous silicon portion 56, and the optional gate cap dielectric 59 constitutes a gate stack (48, 50, 52, 54, 56, 59). The optional chemical oxide portion 48 and the high-k gate dielectric 50 collectively function as a gate dielectric (48, 50) of a transistor to be subsequently formed. In one embodiment, all components of the gate stack (48, 50, 52, 54, 56, 59) can have sidewalls that are vertically coincident among one another, i.e., coincide in a top-down view in a direction perpendicular to the top surface of the semiconductor substrate 8 (such as the top-down view of FIG. 3A).

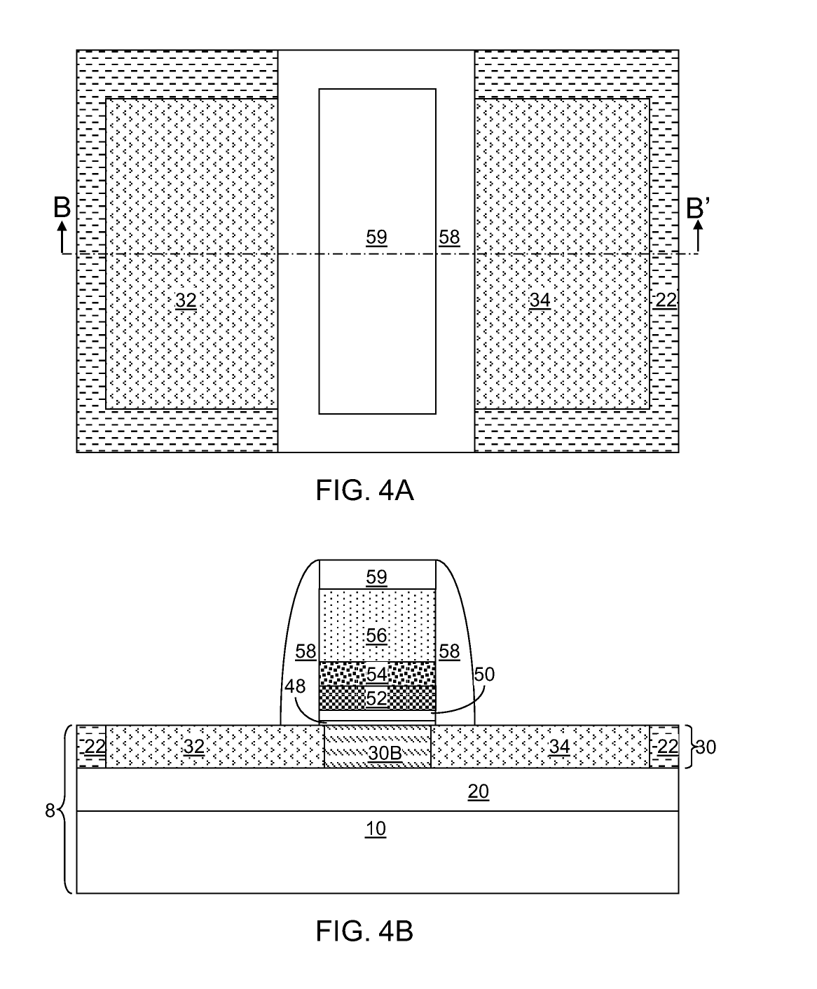

Referring to FIGS. 4A and 4B, electrical dopants of the second conductivity type are implanted into regions of the top semiconductor portion 30′ that do not underlie the gate stack (48, 50, 52, 54, 56, 59). The second conductivity type is the opposite of the first conductivity type, which is the conductivity type of the top semiconductor portion 30′. For example, the first conductivity type can be p-type and the second conductivity type can be n-type, or vice versa. One of the regions implanted with the electrical dopants of the second conductivity type and located on one side of the gate stack (48, 50, 52, 54, 56, 59) is a source extension region 32, and another of the regions implanted with the electrical dopants of the second conductivity type and located on the other side of the gate stack (48, 50, 52, 54, 56, 59) is a drain extension region 34.

A region of the top semiconductor portion 30′ is shielded by the gate stack (48, 50, 52, 54, 56, 59) during the ion implantation, and thus, is not implanted with the electrical dopants of the second conductivity type. This region maintains the doping of the first conductivity type, and is referred to as a body region 30B, which functions as the body of a transistor to be subsequently formed. The body region 30B is laterally contacted by the source extension region 32 and the drain extension region 34.

A gate spacer 58 is formed, for example, by depositing a conformal dielectric material layer and anisotropically etching the conformal dielectric material layer. The gate spacer 58 includes a dielectric material such as silicon oxide, silicon nitride, silicon oxynitride, or a combination thereof. The thickness of the gate spacer 58, as measured at the base that contacts the top surface of the top semiconductor layer 30, can be from 10 nm to 100 nm, although lesser and greater thicknesses can also be employed.

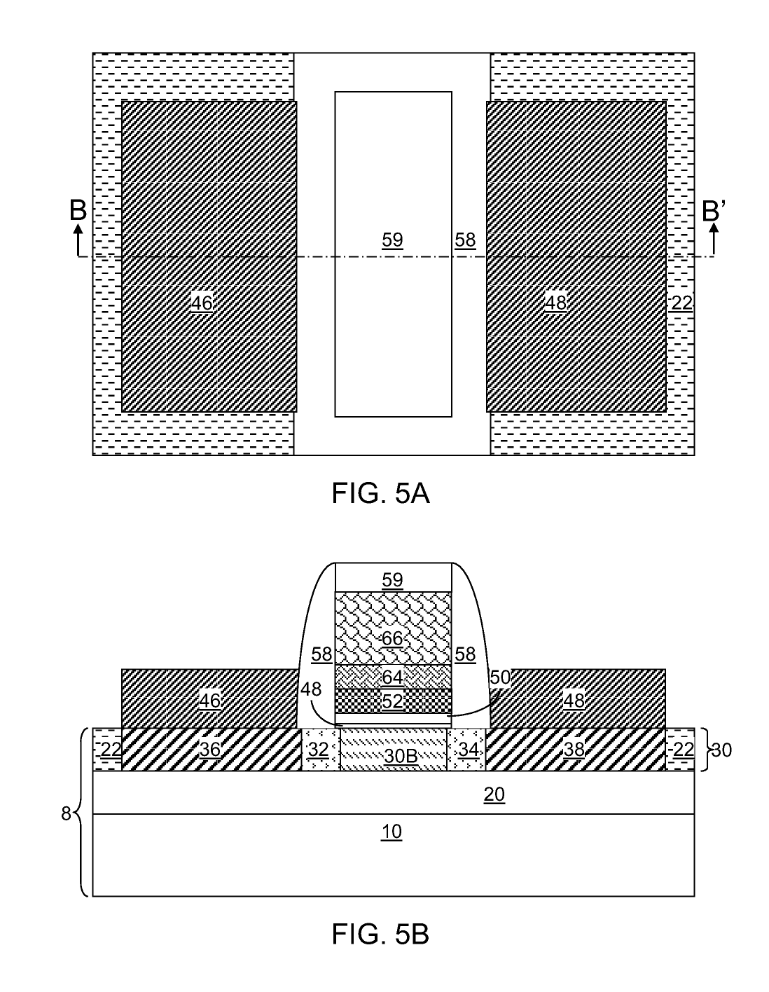

Referring to FIGS. 5A and 5B, selective epitaxy can be optionally performed to deposit an additional semiconductor material to form a raised source region 46 and a raised drain region 48. In one embodiment, the raised source region 46 and the raised drain region 48 can be formed with in-situ doping with electrical dopants of the second conductivity type. In another embodiment, the raised source region 46 and the raised drain region 48 can be formed as undoped (intrinsic) semiconductor material portions and subsequently implanted with electrical dopants of the second conductivity type to become doped semiconductor material portions having a doping of the second conductivity type. The raised source region 46 and the raised drain region 48 can be epitaxially aligned to the underlying single crystalline semiconductor material in the top semiconductor layer 30.

In embodiments in which the raised source region 46 and the raised drain region 48 are formed and in embodiments in which formation of a raised source region and a raised drain region is omitted, source/drain ion implantation can be performed to implant additional electrical dopants of the second conductivity type into portions of the source extension region 32 and the drain extension region 34 that are not covered by the gate stack (48, 50, 52, 54, 56, 59) or the gate spacer 58. In embodiment in which the raised source region 46 and the raised drain region 48 are formed, the source/drain ion implantation can be formed concurrently with ion implantation of the electrical dopants of the second conductivity type into the raised source region 46 and the raised drain region 48. The portion of the source extension region 32 that is implanted with the electrical dopants of the second conductivity type is a buried source region 36. The portion of the drain extension region 34 that is implanted with the electrical dopants of the second conductivity type is a buried drain region 38.

The buried source region 36 has a greater concentration of the electrical dopants of the second conductivity type than the source extension region 32, and the buried drain region 38 has a greater concentration of the electrical dopants of the second conductivity type than the drain extension region 34. The buried source region 36, the raised source region 46, and the source extension region 32 collectively function as a source of a field effect transistor, and the buried drain region 38, the raised drain region 48, and the drain extension region 34 collectively function as a drain of the field effect transistor.

A thermal anneal is performed between the end of the processing steps of FIGS. 2A and 2B before depositing a contact level dielectric material layer above the buried source region 36, the buried drain region 38, the optional raised source region 46, and the optional raised drain region 48 . The thermal anneal can be a stand-alone process that is performed in addition to the processing steps described above, or can be a part of a process that employs an elevated temperature such as selective epitaxy of the raised source region 46 and the raised drain region 48. The temperature of the thermal anneal can be, for example, between 600° C. and 1,200° C., and the time duration of the thermal anneal can be from 1 second to 6 hours, although lesser and greater time duration can also be employed.

The thermal anneal is performed at a temperature at which the amorphous material of the amorphous silicon-germanium alloy layer 54L or the amorphous silicon-germanium alloy portion 54 and the amorphous material of the amorphous silicon layer 56L and the amorphous silicon portion 56 are transformed into polycrystalline material portions. Specifically, the amorphous silicon portion 56 that includes amorphous arsenic-doped silicon is transformed into a polycrystalline arsenic-doped silicon portion 66. If the thermal anneal is performed prior to patterning of the gate stack, the amorphous silicon layer 56L that includes amorphous arsenic-doped silicon is transformed into a polycrystalline arsenic-doped silicon layer, which is subsequently patterned to form the polycrystalline arsenic-doped silicon portion 66. In one embodiment, the polycrystalline arsenic-doped silicon-germanium alloy portion includes germanium at an atomic concentration from 1% to 80%. In another embodiment, the polycrystalline arsenic-doped silicon-germanium alloy portion includes germanium at an atomic concentration from 1% to 50%.

In some embodiments, the amorphous silicon-germanium alloy portion 54 can include an amorphous intrinsic silicon-germanium alloy as discussed above. The amorphous silicon-germanium alloy portion 54 is transformed into a polycrystalline arsenic-doped silicon-germanium alloy portion 64 because arsenic diffuses out of the amorphous arsenic-doped silicon material of the amorphous silicon portion 56 during the thermal anneal.

Thus, despite the absence of arsenic in the amorphous silicon-germanium alloy portion 54, the diffusion of arsenic into the amorphous silicon-germanium alloy portion 54 during the thermal anneal causes the amorphous silicon-germanium alloy portion 54 to be converted into the polycrystalline arsenic-doped silicon-germanium alloy portion 64 by the end of the thermal anneal. The concentration of arsenic in the polycrystalline arsenic-doped silicon-germanium alloy portion 64 can be from 3.0×10¹⁹/cm³ to 3.0×10²¹/cm³, although lesser and greater arsenic concentrations can also be achieved.

If the thermal anneal is performed prior to patterning of the gate stack, the amorphous silicon-germanium alloy layer 54L is transformed into a polycrystalline arsenic-doped silicon-germanium alloy layer, which is subsequently patterned to form the polycrystalline arsenic-doped silicon-germanium alloy portion 64. If the amorphous silicon-germanium alloy layer 56L is an amorphous intrinsic silicon-germanium alloy layer prior to the annealing of the gate stack, the polycrystalline arsenic-doped silicon-germanium alloy portion 64 is formed by diffusion of arsenic from a portion of the amorphous arsenic-doped silicon layer 56L, which can be a bottom portion of the amorphous arsenic-doped silicon layer 56L prior to patterning of the gate stack or a bottom portion of the amorphous arsenic-doped silicon portion 56 after pattering of the gate stack, into the material of the amorphous intrinsic silicon-germanium alloy layer 54L during the annealing, i.e., the thermal anneal.

In some other embodiments, the amorphous silicon-germanium alloy portion 54 can include an amorphous arsenic-doped silicon-germanium alloy as discussed above. The amorphous silicon-germanium alloy portion 54 is transformed into a polycrystalline arsenic-doped silicon-germanium alloy portion 64. If the amorphous silicon portion 56 includes arsenic at a greater concentration that the amorphous silicon-germanium alloy portion 54, for example, by selecting a vertical dopant concentration profile for arsenic during a previous arsenic ion implantation step into the amorphous silicon layer 56L, arsenic can diffuse out of the amorphous arsenic-doped silicon material in the amorphous silicon portion 56 into the amorphous silicon-germanium alloy portion 54 to increase the arsenic concentration in the amorphous silicon-germanium alloy portion 54 during the thermal anneal. The mechanism of acceleration of arsenic diffusion in an amorphous silicon-germanium alloy portion relative to arsenic diffusion in an amorphous silicon portion, which is discussed above, applies to these embodiments, too.

By the end of the thermal anneal, the amorphous silicon-germanium alloy portion 54 is converted into the polycrystalline arsenic-doped silicon-germanium alloy portion 64. The concentration of arsenic in the polycrystalline arsenic-doped silicon-germanium alloy portion 64 can be from 3.0×10¹⁹/cm³ to 3.0×10²¹/cm³, although lesser and greater arsenic concentrations can also be achieved. If the thermal anneal is performed prior to patterning of the gate stack, the amorphous silicon-germanium alloy layer 54L is transformed into a polycrystalline arsenic-doped silicon-germanium alloy layer, which is subsequently patterned to form the polycrystalline arsenic-doped silicon-germanium alloy portion 64.

If the amorphous silicon-germanium alloy layer 54L is deposited with in-situ doping, the concentration of arsenic in the amorphous silicon-germanium alloy layer 54L can be greater than the concentration of arsenic in the subsequently deposited amorphous silicon layer 56L. In this case, the polycrystalline arsenic-doped silicon-germanium alloy portion 64 can have an arsenic concentration that is greater than the arsenic concentration of the polycrystalline arsenic-doped silicon portion 66.

If the thermal anneal is performed after formation of the gate spacer 58, the polycrystalline arsenic-doped silicon-germanium alloy portion 64 and the arsenic concentration of the polycrystalline arsenic-doped silicon portion 66 are laterally confined by the gate spacer 58. Thus, the polycrystalline arsenic-doped silicon-germanium alloy portion 64 and the arsenic concentration of the polycrystalline arsenic-doped silicon portion 66 have sidewalls that are vertically coincident with other elements in the gate stack, i.e., the gate dielectric (48, 50), the metallic material portion 52, and the optional gate cap dielectric 59.

If the thermal anneal is performed prior to patterning of the gate layers to form a gate stack, the gate stack includes, upon formation, the gate dielectric (48, 50), the metallic material portion 52, the polycrystalline arsenic-doped silicon-germanium alloy portion 64, the polycrystalline arsenic-doped silicon portion 66, and the optional gate cap dielectric portion 59. In this case, the polycrystalline arsenic-doped silicon-germanium alloy portion 64 and the arsenic concentration of the polycrystalline arsenic-doped silicon portion 66 have sidewalls that are vertically coincident with other elements in the gate stack, i.e., the gate dielectric (48, 50), the metallic material portion 52, and the optional gate cap dielectric 59.

The presence of the polycrystalline arsenic-doped silicon-germanium alloy portion 64 in the exemplary structure reduces the Schottky barrier, which is inherently present between a semiconductor material and a metal, between the metallic material portion 52 and the semiconductor material of the stack of the polycrystalline arsenic-doped silicon-germanium alloy portion 64 and the polycrystalline arsenic-doped silicon portion 66 relative to a corresponding Schottky barrier in a comparative example in which a polycrystalline arsenic-doped silicon-germanium alloy portion is omitted. This is because an amorphous silicon-germanium alloy is more conducive to diffusion of arsenic than amorphous silicon. In the exemplary structure, a semiconductor material layer having a greater concentration of arsenic in the form of the polycrystalline arsenic-doped silicon-germanium alloy portion 64 is provided at the interface that causes the Schottky barrier relative to the comparative example in which a polycrystalline arsenic-doped silicon-germanium alloy portion is not present. Thus, the exemplary structure of the present disclosure lowers the resistivity of the semiconductor material near the interface at which the Schottky barrier is present, thereby enhancing the conductivity in the semiconductor material at the interface of the Schottky barrier and reducing the height of the Schottky barrier relative to the comparative example in which a polycrystalline arsenic-doped silicon-germanium alloy portion is not present.

Furthermore, a silicon-germanium alloy has a narrower band gap width than silicon. By reducing the band gap width of the semiconductor material at the interface of the Schottky barrier by providing the polycrystalline arsenic-doped silicon-germanium alloy portion 64, the height of the Schottky barrier is further reduced relative to the comparative example in which a polycrystalline arsenic-doped silicon-germanium alloy portion is not present. The reduction of the Schottky barrier provides enhanced high frequency characteristics for the gate electrode, which includes the metallic material portion 52, the polycrystalline arsenic-doped silicon-germanium alloy portion 64, and the polycrystalline arsenic-doped silicon portion 66 in the exemplary structure.

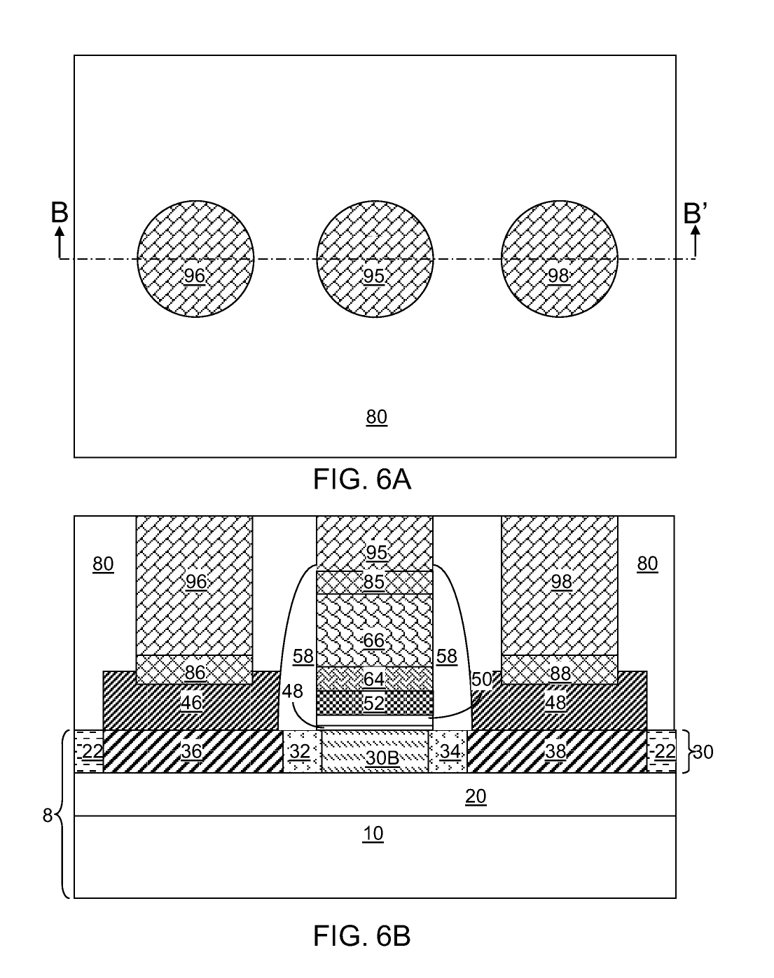

Referring to FIGS. 6A and 6B, a contact-level dielectric layer 80 is deposited over the gate stack, the gate spacer 58, the source (32, 36, 46), and the drain (34, 38, 48) of the field effect transistor. Various contact via structures can be formed in the contact-level dielectric layer 80, which can include a source-side contact via structure 96, a drain-side contact via structure 98, and a gate-side contact via structure 95. Optionally, various metal semiconductor alloy portions including a metal semiconductor alloy, such as a metal silicide, can be formed. The various metal semiconductor alloy portions can include, for example, a source-side metal semiconductor alloy portion 86, a drain-side metal semiconductor alloy portion 88, and a gate-side metal semiconductor alloy portion 85.

While the disclosure has been described in terms of specific embodiments, it is evident in view of the foregoing description that numerous alternatives, modifications and variations will be apparent to those skilled in the art. Accordingly, the disclosure is intended to encompass all such alternatives, modifications and variations which fall within the scope and spirit of the disclosure and the following claims.

What is claimed is:

1. A method of forming a semiconductor structure comprising:
forming a gate dielectric layer on a semiconductor substrate;
forming a metallic material layer on said gate dielectric layer;
forming a layer stack of an amorphous silicon-germanium alloy layer and an amorphous arsenic-doped silicon layer on said metallic material layer;
forming a gate stack by patterning said layer stack, said metallic material layer, and said gate dielectric layer; and
annealing said gate stack, wherein a gate electrode including a stack of a polycrystalline arsenic-doped silicon-germanium alloy portion and an polycrystalline arsenic-doped silicon portion is formed within said gate stack.

2. The method of claim 1, wherein said amorphous silicon-germanium alloy layer is an amorphous arsenic-doped silicon-germanium alloy layer.

3. The method of claim 2, wherein said amorphous arsenic-doped silicon-germanium alloy layer is formed by depositing an amorphous silicon-germanium alloy with in-situ arsenic doping.

4. The method of claim 3, wherein said amorphous arsenic-doped silicon layer is formed by depositing amorphous silicon with in-situ arsenic doping.

5. The method of claim 3, wherein said amorphous arsenic-doped silicon layer is formed by:
depositing an amorphous intrinsic silicon-germanium alloy layer; and
implanting arsenic into said amorphous intrinsic silicon-germanium alloy layer.

6. The method of claim 2, wherein said amorphous arsenic-doped silicon-germanium alloy layer formed by:
depositing an amorphous intrinsic silicon-germanium alloy layer; and
introducing arsenic into said amorphous intrinsic silicon-germanium alloy layer.

7. The method of claim 6, further comprising:
depositing an amorphous silicon layer on said amorphous intrinsic silicon-germanium alloy layer; and
implanting arsenic into said amorphous intrinsic silicon-germanium alloy layer and said amorphous silicon layer by ion implantation, wherein arsenic is introduced into said amorphous intrinsic silicon-germanium alloy layer during said implanting.

8. The method of claim 6, further comprising implanting arsenic into said amorphous intrinsic silicon-germanium alloy layer prior to forming said amorphous arsenic-doped silicon layer.

9. The method of claim 1, wherein said amorphous silicon-germanium alloy layer is an amorphous intrinsic silicon-germanium alloy layer prior to said annealing of said gate stack, and said polycrystalline arsenic-doped silicon-germanium alloy portion is formed by diffusion of arsenic from a portion of said amorphous arsenic-doped silicon layer into a material of said amorphous intrinsic silicon-germanium alloy layer during said annealing.

10. The method of claim 8, wherein said amorphous arsenic-doped silicon layer is formed by depositing amorphous silicon with in-situ arsenic doping.

11. The method of claim 8, wherein said amorphous arsenic-doped silicon layer is formed by:
depositing an amorphous intrinsic silicon-germanium alloy layer; and
implanting arsenic into said amorphous intrinsic silicon-germanium alloy layer.

12. The method of claim 1, wherein said gate dielectric layer includes a metal oxide having a dielectric constant greater than 8.0.

13. A semiconductor structure comprising a field effect transistor, said field effect transistor including a gate stack comprising:
a gate dielectric located on a semiconductor substrate;
a metallic material portion contacting said gate dielectric;
a polycrystalline arsenic-doped silicon-germanium alloy portion contacting said metallic material portion; and
an polycrystalline arsenic-doped silicon portion contacting said polycrystalline arsenic-doped silicon-germanium alloy portion.

14. The semiconductor structure of claim 13, wherein said polycrystalline arsenic-doped silicon-germanium alloy portion includes germanium at an atomic concentration from 1% to 80%.

15. The semiconductor structure of claim 13, wherein said polycrystalline arsenic-doped silicon-germanium alloy portion has an arsenic concentration that is greater than an arsenic concentration of said polycrystalline arsenic-doped silicon portion.

16. The semiconductor structure of claim 13, wherein said field effect transistor includes a channel comprising a semiconductor material, and said metallic material portion includes a metallic material having a work function that is between a mid-bandgap energy level of said semiconductor material and a balance band energy level of said semiconductor material.

17. The semiconductor structure of claim 13, wherein said field effect transistor includes a channel comprising a semiconductor material, and said metallic material portion includes a metallic material having a work function that is between a mid-bandgap energy level of said semiconductor material and a conduction band energy level of said semiconductor material.

18. The semiconductor structure of claim 13, wherein said gate dielectric includes a metal oxide having a dielectric constant greater than 8.0.

19. The semiconductor structure of claim 13, wherein said metallic material portion includes a material selected from TiN, TaN, TaC, a TiN/TaAlN stack, and a TiN/Al/TiN stack.

20. The semiconductor structure of claim 13, wherein said gate dielectric, said metallic material portion, said polycrystalline arsenic-doped silicon-germanium alloy portion, and said polycrystalline arsenic-doped silicon portion have sidewalls that are vertically coincident among one another.
